(19) United States
(12) Patent Application Publication
(10) Pub. No.: US 2026/0218381 A1
(43) Pub. Date: Jul. 30, 2026

(54) SYSTEMS FOR CONTROLLED PRECURSOR DELIVERY TO A PLURALITY OF DEPOSITION CHAMBERS AND RELATED METHODS

(71) Applicant: ENTEGRIS, INC., Billerica, MA (US)

(72) Inventors: Bryan C. Hendrix, Danbury, CT (US); Lucas B. Henderson, Danbury, CT (US)

(21) Appl. No.: 19/458,379

(22) Filed: Jan. 23, 2026

Related U.S. Application Data
(60) Provisional application No. 63/749,530, filed on Jan. 25, 2025.

(51) Int. Cl. C23C 16/52; C23C 16/455

(52) U.S. Cl. CPC C23C 16/52; C23C 16/45544

(57) ABSTRACT

Systems for controlled precursor delivery to a plurality of deposition chambers and related methods are provided. The system comprises a control valve. The control valve is configured to control a flow of a carrier gas from a carrier gas source to a precursor vessel containing a precursor. The system comprises a pressure sensor. The pressure sensor is configured to measure a pressure of a vapor comprising at least one of the carrier gas, the precursor, or any combination thereof. The system comprises a controller. The controller communicates with the control valve and the pressure sensor. The controller is configured to adjust the control valve based on the pressure measured by the at least one pressure sensor, such that, when the vapor is delivered to the plurality of deposition chambers at different flow rates, a concentration of the carrier gas and the precursor is substantially constant.

### CROSS-REFERENCE TO RELATED APPLICATIONS

This application claims the benefit under 35 USC 119 of U.S. Provisional Patent Application No. 63/749,530, filed Jan. 25, 2025, the disclosure of which is hereby incorporated herein by reference in its entirety.

### FIELD

The present disclosure relates to systems for controlled precursor delivery to a plurality of deposition chambers, and related systems and related methods.

### BACKGROUND

Vapor deposition processes can involve delivering precursors to tools. At the tool, the precursors are deposited onto a substrate.

### SUMMARY

Some embodiments relate to a system. In some embodiments, the system comprises a control valve. In some embodiments, the control valve is configured to control a flow of a carrier gas from a carrier gas source to a precursor vessel containing a precursor. In some embodiments, the system comprises a pressure sensor. In some embodiments, the pressure sensor is configured to measure a pressure of a vapor comprising at least one of the carrier gas, the precursor, or any combination thereof. In some embodiments, the system comprises a controller. In some embodiments, the controller communicates with the control valve and the pressure sensor. In some embodiments, the controller is configured to adjust the control valve based on the pressure measured by the at least one pressure sensor, such that, when the vapor is delivered to the plurality of deposition chambers at different flow rates, a concentration of the carrier gas and the precursor is substantially constant.

Some embodiments relate to a system. In some embodiments, the system comprises a precursor vessel fluidly coupled to a carrier gas source. In some embodiments, the precursor vessel is configured to contain a precursor. In some embodiments, the precursor vessel is configured to deliver a vapor including the precursor and a carrier gas, to a plurality of deposition chambers. In some embodiments, the system comprises at least one pressure sensor. In some embodiments, the at least one pressure sensor is located in a flow path of the vapor between a control valve and the plurality of deposition chambers. In some embodiments, the system comprises a control valve. In some embodiments, the control valve is configured to maintain a sensed total pressure. In some embodiments, the control valve is located in a flow path of the carrier gas at a location upstream of the precursor vessel.

Some embodiments relate to a method. In some embodiments, the method comprises flowing a vapor comprising a vaporized precursor and a carrier gas, from a precursor vessel to a plurality of deposition chambers. In some embodiments, the method comprises measuring a pressure of the vapor comprising the vaporized precursor and the carrier gas, at a location upstream of the plurality of deposition chambers. In some embodiments, the method comprises controlling, via the control valve, a carrier gas flow from a carrier gas source to the precursor vessel, based on the measured pressure, to maintain a concentration of the vaporized precursor and/or the carrier gas, in the vapor, at or about a set point concentration. In some embodiments, the method comprises adjusting the set point concentration to a second set point concentration. In some embodiments, the method comprises adjusting a flowrate of the vapor comprising the vaporized precursor and the carrier gas, to at least one of the plurality of deposition chambers.

### DRAWINGS

FIG. 1 is a schematic diagram of a system for precursor delivery, according to some embodiments.

FIG. 2 is a schematic diagram of a system for precursor delivery, according to some embodiments.

FIG. 3 is a schematic diagram of a system for precursor delivery, according to some embodiments.

FIG. 4 is a schematic diagram of a system for precursor delivery, according to some embodiments.

FIG. 5 is a schematic diagram of a system for precursor delivery, according to some embodiments.

FIG. 6 is a flowchart of a method for delivering a precursor, according to some embodiments.

FIG. 7 is a schematic diagram of a prior art system for precursor delivery which exhibits several challenges solved by the present invention.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

Systems and methods for controlling precursor delivery to a plurality of deposition chambers are provided. The systems and methods disclosed herein are capable of adjustably controlling a relative concentration of different vapors in a mixed-vapor feed to a plurality of deposition chambers. The systems and methods disclosed herein can adjustably maintain a relative concentration of different vapors in a mixed-vapor feed from a single precursor vessel to a plurality of deposition chambers. The systems and methods disclosed herein can adjustably maintain a relative concentration of different vapors in a mixed-vapor feed from a single precursor vessel to a plurality of deposition chambers, even where each of the plurality of deposition chambers independently control flowrate. The systems and methods disclosed herein can adjustably maintain a relative concentration of different vapors in a mixed-vapor feed from a single precursor vessel to a plurality of deposition chambers, even where there is variable flow in a carrier gas and/or vaporized precursor.

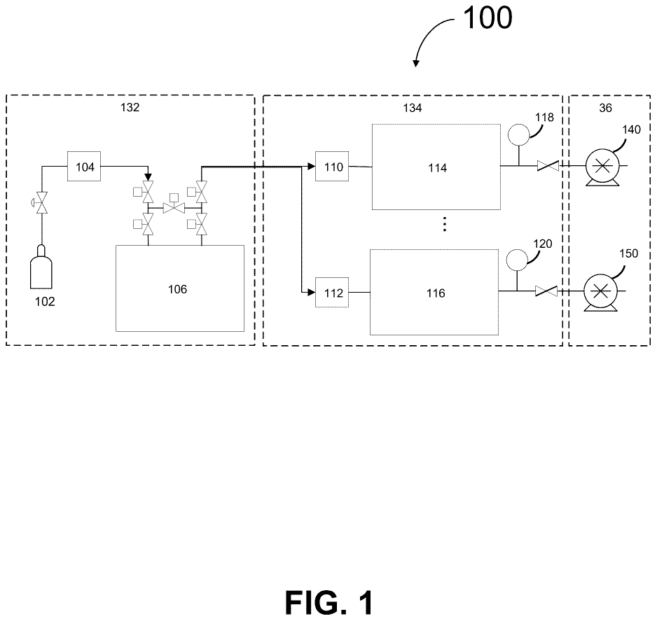

FIG. 1 is a schematic diagram of a system for controlling precursor delivery to a plurality of deposition chambers, according to some embodiments. As shown in FIG. 1, in some embodiments, the system 100 comprises a carrier gas source 102, a precursor vessel 106, and a plurality of deposition chambers, such as, for example and without limitation, deposition chamber 114 and deposition chamber 116. Although two deposition chambers are shown, it will be appreciated that the system 100 can comprise additional deposition chambers, without departing from the scope of this disclosure. The precursor vessel 106 can comprise a single precursor vessel configured to vaporize a precursor for delivery to deposition chamber 114 and deposition chamber 116. The carrier gas source 102 can be fluidly connectable to the precursor vessel 106 and can be configured to supply a carrier gas to the precursor vessel 106. When a carrier gas is supplied to the precursor vessel 106, the vapor exiting the precursor vessel 106 can comprise both the carrier gas and the vaporized precursor, for example, as a mixed-vapor feed.

As shown in FIG. 1, each of the plurality of deposition chambers can be configured to independently control flow of the vapor to each respective deposition chamber. For example, in some embodiments, the deposition chamber 114 has a flow controller 110, and the deposition chamber 116 has a flow controller 112. In conventional systems, when multiple deposition chambers are receiving different flowrates of the vapor comprising the carrier gas and the vaporized precursor in, for example, a single mixed-vapor feed, the concentration or relative amounts of each cannot be controlled and thus vary over time. At least one reason for this is because different flowrates result in variable carrier gas flow, making it difficult to maintain a concentration of the carrier gas and vaporized precursor at or about an adjustable set point concentration. The system 100 overcomes at least these and other challenges associated with adjustably controlling concentration of different vapors to multiple deposition chambers.

The system 100 can comprise a control valve 104 and at least one pressure sensor 118, 120. The control valve 104 can be provided at a location between the carrier gas source 102 and the precursor vessel 106. The at least one pressure sensor 118, 120 can be provided at a location between the control valve 104 and the plurality of deposition chambers 114, 116. To adjustably control a concentration of different vapors in the feed to the plurality of deposition chambers 114, 116, in some embodiments, the at least one pressure sensor 118, 120 can be configured to measure directly or indirectly a total pressure within the precursor vessel 106, while the control valve 104 can be configured to adjust a flowrate of the carrier gas flowing to the precursor vessel 106, so as to maintain a total pressure within the precursor vessel 106 and, as a result, also maintain a concentration of the carrier gas and/or the vaporized precursor at or about a set point concentration. In some embodiments, the vapor can be fed at different flowrates to each of the plurality of deposition chambers 114, 116, while also maintaining a concentration, or more generally relative amounts, of the vapors at or about a set point concentration, which can be adjusted as necessary.

A concentration of the vapor comprising the vaporized precursor and the carrier gas can be calculated based on the following formula:

$${C}_{v} = \frac{{F}_{v}}{{F}_{car}} = \frac{{P}_{v}}{{P}_{T} - {P}_{v}}$$

where:
Fᵥ is the flowrate of the vaporized precursor;
F_{car} is the flowrate of the carrier gas;
P_{T} is the total pressure of vapor; and
Pᵥ is the partial pressure of the vaporized precursor.

In some embodiments, the total pressure of vapor is a total pressure of vapor in the precursor vessel and the partial pressure of the vaporized precursor is a partial pressure of the vaporized precursor in the precursor vessel 106. In some embodiments, the total pressure of vapor is a total pressure of vapor in a conduit (e.g., a gas line) and the partial pressure of the vaporized precursor is a partial pressure of the vaporized precursor in the conduit (e.g., the gas line).

In some embodiments, the system 100 comprises a controller— or a processor, or other similar device—that communicates with the control valve 104 and the at least one pressure sensor 118, 120. The controller can be configured to adjust the control valve based on the pressure measured by the at least one pressure sensor, such that, when the vapor is delivered to the plurality of deposition chambers 114, 116 at different flow rates, a concentration of the carrier gas and/or the vaporized precursor is substantially constant. In some embodiments, a concentration is substantially constant when a concentration (e.g., vapor pressure or partial vapor pressures, concentration based on volume, concentration based on mass, etc.) is maintained within 5% of a set point concentration, or any range or subrange between 0.1% and 5%. For example, in some embodiments, a concentration is substantially constant when a concentration is maintained within 0.5% to 4%, 1% to 3%, 0.1% to 5%, 0.5% to 5%, 1% to 5%, 2% to 5%, 3% to 5%, 4% to 5%, 0.1% to 4%, 0.1% to 3%, 0.1% to 2%, or 0.1% to 1% of a set point concentration.

As mentioned above, the control valve 104 can be located between the carrier gas source 102 and the precursor vessel 106. In some embodiments, the control valve 104 is located between the precursor vessel 106 and each of the plurality of depositions chambers. 114, 116. In some embodiments, the control valve 104 is located at the outlet of the carrier gas source 102.

The control valve 104 can comprise a device for controlling delivery of a vapor. In some embodiments, the control valve 104 is configured to adjustably control a flow of a carrier gas from a carrier gas source 102 to a precursor vessel 106 containing a precursor. In some embodiments, for example, the control valve 104 comprises a downstream pressure controller. In some embodiments, the control valve 104 comprises a variable orifice valve. In some embodiments, the control valve 104 comprises an electrovalve. It will be appreciated that other types of control valves can be used herein, without departing from the scope of this disclosure.

The control valve can be located on a sub-fabrication area 132 of a semiconductor manufacturing facility. In some embodiments, the control valve is not located on a sub-fabrication area 132 of a semiconductor manufacturing facility.

As mentioned above, the at least one pressure sensor 118, 120 can be located between the control valve 104 and the plurality of deposition chambers 114, 116. In some embodiments, the at least one pressure sensor 118, 120 is located within the precursor vessel 106 and thus directly measures a total pressure within the precursor vessel 106. In some embodiments, the at least one pressure sensor 118, 120 is provided at another location which is not within the precursor vessel 106 (e.g., the at least one pressure sensor indirectly measures a total pressure within the pressure vessel). In some embodiments, the at least one pressure sensor 118, 120 is located between the precursor vessel 106 and the plurality of deposition chambers 14, 116. In some embodiments, the at least one pressure sensor 118, 120 is located between the precursor vessel 106 and the flow controllers 110, 112 for each of the plurality of deposition chambers 114, 116. In some embodiments, the at least one pressure sensor 118, 120 comprises a first pressure sensor and a second pressure sensor. In some embodiments, the first pressure sensor is located between the control valve 104 and the precursor vessel 106. In some embodiments, the second pressure sensor is located between the precursor vessel 106 and the plurality of deposition chambers 114, 116.

The at least one pressure sensor 118, 120 can comprise a device for directly or indirectly measuring a pressure. In some embodiments, the at least one pressure sensor 118, 120 is a gauge pressure sensor. In some embodiments, the at least one pressure sensor 118, 120 is a differential pressure sensor. In some embodiments, the at least one pressure sensor 118, 120 is a vacuum pressure sensor.

The carrier gas source 102 can comprise a carrier gas. In some embodiments, the carrier gas comprises at least one of an inert gas, an inert vapor, or any combination thereof. In some embodiments, a gas and/or a vapor is inert when the gas and/or the vapor does not react chemically with other substances under specified conditions. In some embodiments, the carrier gas comprises at least one of argon, nitrogen, or a combination thereof. In some embodiments, the carrier gas comprises argon. In some embodiments, the carrier gas comprises nitrogen.

The carrier gas source 102 can comprise a plurality of carrier gas sources that feed to a precursor vessel 106. The plurality of carrier gas sources can be mixed prior to feeding to a precursor vessel 106. The plurality of carrier gas sources can be mixed prior to feeding to a precursor vessel 106. The plurality of carrier gas sources can be mixed at a precursor vessel 106.

The precursor vessel 106 can be an ampoule. In some embodiments, the precursor vessel 106 is contained within a cabinet. The precursor vessel 106 can be configured to contain a precursor. The precursors can be useful in vapor deposition processes. Examples of deposition processes include, without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

The precursor may exist in a solid or liquid phase and can be vaporized (e.g., via heating) to obtain a vapor of the precursor. In some embodiments, the precursor comprises at least one of dimethyl hydrazine, trimethyl aluminum (TMA), hafnium chloride (HfCl₄), zirconium chloride (ZrCl₄), tungsten chloride (WCl₅), molybdenum chloride, indium trichloride, indium monochloride, aluminum trichloride, titanium iodide, tungsten carbonyl, Ba(DPM)₂, bis dipivaloyl methanato strontium (Sr(DPM)₂), TiO(DPM)₂, tetra dipivaloyl methanato zirconium (Zr(DPM)₄), decaborane, octadecaborane, boron-containing prescursors, indium-containing precursors, antimony-containing precursors, phosphorous-containing precursors, arsenic-containing precursors, precursors incorporating alkyl-amidinate ligands, organometallic precursors, alkali earth metals-RCp₂, Sc-RCp₃, Y-RCp₃, lanthanide-RCp₃, zirconium tertiary butoxide (Zr(t-OBu)₄), tetrakisdiethylaminozirconium (Zr(NEt₂)₄), tetrakisdiethylaminohafnium (Hf(NEt₂)₄), tetrakis(dimethylamino) titanium (TDMAT), tertbutyliminotris(diethylamino) tantalum (TBTDET), pentakis (dimethylamino) tantalum (PDMAT), pentakis (ethylmethylamino) tantalum (PEMAT), tetrakisdimethylaminozirconium (Zr(NMe₂)₄), hafniumtertiarybutoxide (Hf(tOBu)₄), xenon difluoride (XeF₂), xenon tetrafluoride (XeF₄), xenon hexafluoride (XeF₆), or any combination thereof.

In some embodiments, the precursor comprises at least one of decaborane, hafnium tetrachloride, zirconium tetrachloride, indium trichloride, metalorganic β-diketonate complexes, cyclopentadienylcycloheptatrienyl-titanium (CpTiCht), aluminum trichloride, titanium iodide, cyclooctatetraenecyclo-pentadienyltitanium, biscyclopentadienyltitaniumdiazide, trimethyl gallium, trimethyl indium, aluminum alkyls like trimethylaluminum, triethylaluminum, trimethylamine alane, dimethyl zinc, tetramethyl tin, trimethyl antimony, diethyl cadmium, tungsten carbonyl, or any combination thereof.

In some embodiments, the precursor comprises at least one of elemental metal, metal halides, metal oxyhalides, metalorganic complexes, or any combination thereof. For example, in some embodiments, the precursor material comprises, consists of, or consists essentially of, or is selected from the group consisting of, at least one of elemental boron, copper, phosphorus, decaborane, gallium halides, indium halides, antimony halides, arsenic halides, gallium halides, aluminum iodide, titanium iodide, MoO₂Cl₂, MoOCl₄, MoCl₅, WCl₅, WOCl₄, WCl₆, cyclopentadienylcycloheptatrienyltitanium (CpTiCht), cyclooctatetraenecyclopenta-dienyltitanium, biscyclopentadienyltitanium-diazide, In(CH₃)₂(hfac), dibromomethyl stibine, tungsten carbonyl, metalorganic β-diketonate complexes, metalorganic alkoxide complexes, metalorganic carboxylate complexes, metalorganic aryl complexes, metalorganic amido complexes, or any combination thereof.

The plurality of deposition chambers 114, 116 can comprise two deposition chambers to ten deposition chambers, or any range or subrange between two deposition chambers and ten deposition chambers. For example, in some embodiments, the plurality of deposition chambers is from three deposition chambers to nine deposition chambers, four deposition chambers to eight deposition chambers, or five deposition chambers to seven deposition chambers. In some embodiments, the plurality of deposition chambers is from two deposition chambers to nine deposition chambers, two deposition chambers to eight deposition chambers, two deposition chambers to seven deposition chambers, two deposition chambers to six deposition chambers, two deposition chambers to five deposition chambers, two deposition chambers to four deposition chambers, or two deposition chambers to three deposition chambers. In some embodiments, the plurality of deposition chambers is from three deposition chambers to ten deposition chambers, four deposition chambers to ten deposition chambers, five deposition chambers to ten deposition chambers, six deposition chambers to ten deposition chambers, seven deposition chambers to ten deposition chambers, eight deposition chambers to ten deposition chambers, or nine deposition chambers to ten deposition chambers.

The plurality of deposition chambers 114, 116 can have a pressure of 0.5 Torr to 500 Torr, or any range or subrange between 0.5 Torr and 500 Torr. For example, in some embodiments, the plurality of deposition chambers 114, 116 can have a pressure of 1 Torr to 450 Torr, 5 Torr to 400 Torr, 10 Torr to 350 Torr, 50 Torr to 300 Torr, 100 Torr to 250 Torr, or 150 Torr to 200 Torr. In some embodiments, the plurality of deposition chambers 114, 116 can have a pressure of 1 Torr to 500 Torr, 5 Torr to 500 Torr, 10 Torr to 500 Torr, 50 Torr to 500 Torr, 100 Torr to 500 Torr, 150 Torr to 500 Torr, 200 Torr to 500 Torr, 250 Torr to 500 Torr, 300 Torr to 500 Torr, 350 Torr to 500 Torr, 400 Torr to 500 Torr, or 450 Torr to 500 Torr. In some embodiments, the plurality of deposition chambers 114, 116 can have a pressure of 0.5 Torr to 450 Torr, 0.5 Torr to 400 Torr, 0.5 Torr to 350 Torr, 0.5 Torr to 300 Torr, 0.5 Torr to 250 Torr, 0.5 Torr to 200 Torr, 0.5 Torr to 150 Torr, 0.5 Torr to 100 Torr, 0.5 Torr to 50 Torr, 0.5 Torr to 10 Torr, 0.5 Torr to 5 Torr, or 0.5 Torr to 1 Torr.

In some embodiments, when a single deposition chamber is present, the total pressure of the precursor vessel 106 is less than 5% of the deposition chamber. In some embodiments, when a single deposition chamber is present, the total pressure of the precursor vessel 106 is less than 10%, less than 15%, less than 20%, less than 25%, less than 30%, less than 35%, less than 40%, less than 45%, less than 50% of the deposition chamber.

In some embodiments, the total pressure is determined by the carrier gas. In some embodiments, the partial pressure is determined by the carrier gas.

In some embodiments, the total pressure of the precursor vessel 106 is greater than a deposition pressure.

In some embodiments, the vapor is delivered to the plurality of deposition chambers 114, 116 at a substantially constant concentration.

Each of the plurality of deposition chambers 114, 116 can comprise a flow controller 110, 112 for independently controlling a flow rate of the vapor to each of the plurality of deposition chambers. The flow controller 110, 112 can comprise at least one of a pneumatic flow controller, an electronic controller, a mass flow controller, a volumetric flow controller, a proportional flow controller, a restricted flow orifice element, or any combination thereof.

In some embodiments, each of the plurality of deposition chambers 114, 116 is configured to receive the vapor at an independently adjustable flowrate. In some embodiments, independently adjustable flow rate comprises each of the plurality of deposition 114, 116 being configured to receive the vapor at different flowrates. For example, in some embodiments, a flow rate of the vapor to deposition chamber 114 is different from a flow rate of the vapor to deposition chamber 116.

In some embodiments, the flow controller 110, 112 is located in a flow path of the vapor. In some embodiments, the flow controller 110, 112 is provided within a fabrication area 134. In some embodiments, the flow controller 110, 112 is provided at a location downstream of the carrier gas source 102. In some embodiments, the flow controller 110, 112 is provided at a location downstream of a control valve 104. In some embodiments, the flow controller 110, 112 is provided at a location downstream of a precursor vessel 106.

In some embodiments, the carrier gas source 102 is located in a sub-fabrication area 132. In some embodiments, the precursor vessel 106 is located in the sub-fabrication area 132. In some embodiments, the control valve 104 is located in the sub-fabrication area 132.

In some embodiments, the carrier gas source 102 is located in a sub-fabrication area. In some embodiments, the precursor vessel 106 is located in the sub-fabrication area. In some embodiments, the control valve 104 is located in a fabrication area.

In some embodiments, the flow controller 110, 112 is located in a fabrication area 134. In some embodiments, the plurality of deposition chambers 114, 116 is located in a fabrication area 134.

A plurality of pumps 140, 150 located in a sub-fabrication area 136 can be used to achieve low pressure in the deposition chambers. In some embodiments, the plurality of pumps 140, 150 are vacuum pumps.

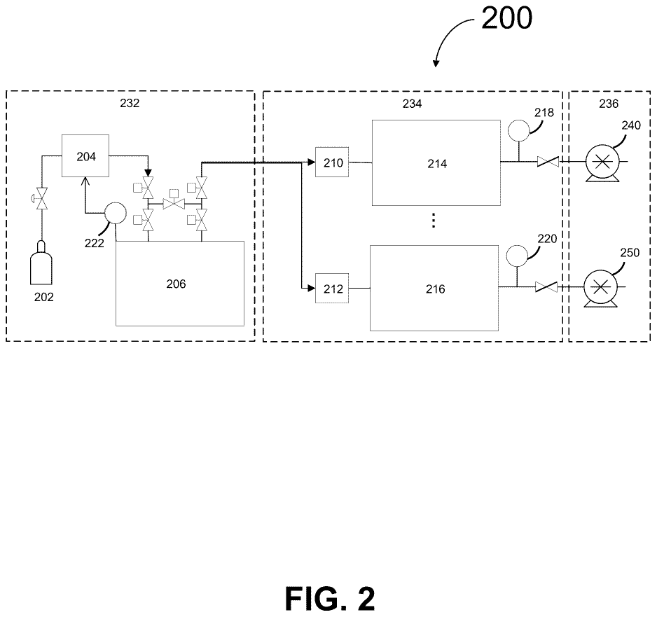

FIG. 2 is a schematic diagram of a system 200 for precursor delivery, according to some embodiments. The system 200 for precursor delivery is same or similar to the system 100 for precursor delivery. Accordingly, similar reference numbers are used. Some of the differences between the system 200 for precursor delivery and the system 100 for precursor delivery are discussed. It will, however, be appreciated that other differences may exist, without departing from the scope of this disclosure.

As shown in FIG. 2, in some embodiments, the system 200 for precursor delivery comprises a carrier gas source 202, a precursor vessel 206, and a plurality of deposition chambers, such as, for example and without limitation, deposition chamber 214 and deposition chamber 216. At least one pressure sensor 222 can be provided at the precursor vessel 206. That is, the at least one pressure sensor 222 can be configured to directly measure a pressure (e.g., a total pressure) within the precursor vessel 206. A downstream pressure controller 204 can be provided at a location between the carrier gas source 202 and the precursor vessel 206. In some embodiments, the downstream pressure controller 204 comprises a control valve and a controller in a single unit. For example, the downstream pressure controller 204 can be configured to control a carrier gas flow from the carrier gas source 202 to the precursor vessel 206 based on the pressure measured by the at least one pressure sensor 222. In addition, deposition chamber 214 can communicate with a flow controller 210, a pressure sensor 218, and a pump 240; and deposition chamber 216 can communicate with a flow controller 212, a pressure sensor 220, and a pump 250.

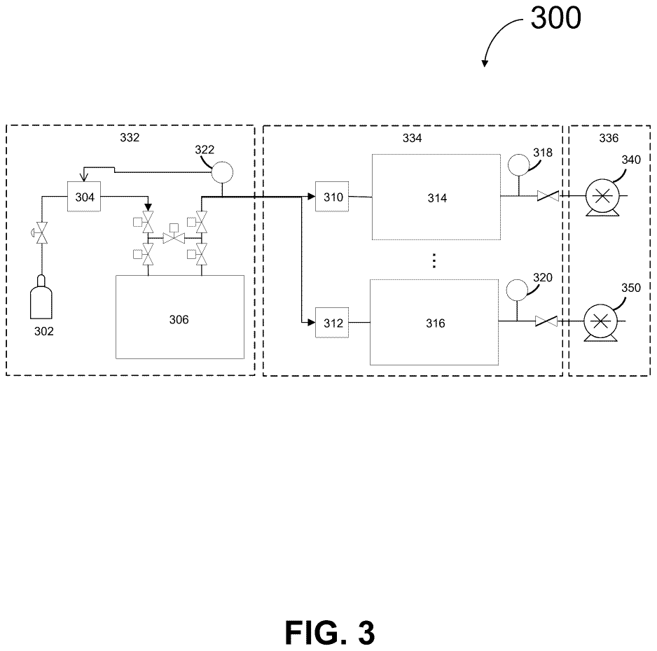

FIG. 3 is a schematic diagram of a system 300 for precursor delivery, according to some embodiments. The system 300 for precursor delivery is same or similar to the system 200 for precursor delivery. Accordingly, similar reference numbers are used. Some of the differences between the system 300 for precursor delivery and the system 200 for precursor delivery are discussed. It will, however, be appreciated that other differences may exist, without departing from the scope of this disclosure.

As shown in FIG. 3, in some embodiments, the system 300 for precursor delivery comprises a carrier gas source 302, a precursor vessel 306, and a plurality of deposition chambers, such as, for example and without limitation, deposition chamber 314 and deposition chamber 316. At least one pressure sensor 322 can be provided at the outlet of the precursor vessel 306. That is, the at least one pressure sensor 322 can be configured to indirectly measure a pressure (e.g., a total pressure) within the precursor vessel 306 from the pressure of the vapor at the outlet of precursor vessel 308. A downstream pressure controller 304 can be provided at a location between the carrier gas source 302 and the precursor vessel 306. In some embodiments, the downstream pressure controller 304 comprises a control valve and a controller in a single unit. For example, the downstream pressure controller 304 can be configured to control a carrier gas flow from the carrier gas source 302 to the precursor vessel 306 based on the pressure measured by the at least one pressure sensor 322. In addition, deposition chamber 314 can communicate with a flow controller 310, a pressure sensor 318, and a pump 340; and deposition chamber 316 can communicate with a flow controller 312, a pressure sensor 320, and a pump 350.

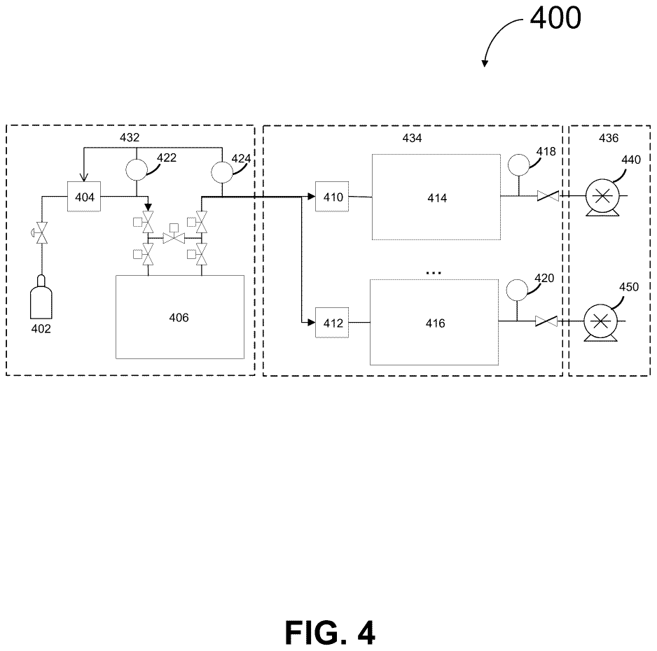

FIG. 4 is a schematic diagram of a system 400 for precursor delivery, according to some embodiments. The system 400 for precursor delivery is same or similar to the system 300 for precursor delivery. Accordingly, similar reference numbers are used. Some of the differences between the system 400 for precursor delivery and the system 300 for precursor delivery are discussed. It will, however, be appreciated that other differences may exist, without departing from the scope of this disclosure.

As shown in FIG. 4, in some embodiments, the system 400 for precursor delivery comprises a carrier gas source 402, a precursor vessel 406, and a plurality of deposition chambers, such as, for example and without limitation, deposition chamber 414 and deposition chamber 416. At least one pressure sensor 422 can be provided at the inlet of the precursor vessel 406 and at least one pressure sensor 424 can be provided at the outlet of the precursor vessel 406. That is, the at least one pressure sensor 422, 424 can be configured to indirectly measure a pressure (e.g., a total pressure) within the precursor vessel 406 from the differential pressure between the at least one pressure sensor 422 at the inlet of the precursor vessel 406 and the at least one pressure sensor 424 at the outlet of the precursor vessel 406. A downstream pressure controller 404 can be provided at a location between the carrier gas source 402 and the precursor vessel 406. In some embodiments, the downstream pressure controller 404 comprises a control valve and a controller in a single unit. For example, the downstream pressure controller 404 can be configured to control a carrier gas flow from the carrier gas source 402 to the precursor vessel 406 based on the differential pressure measured by the at least one pressure sensor 422, 424. In addition, deposition chamber 414 can communicate with a flow controller 410, a pressure sensor 418, and a pump 440; and deposition chamber 416 can communicate with a flow controller 412, a pressure sensor 420, and a pump 450.

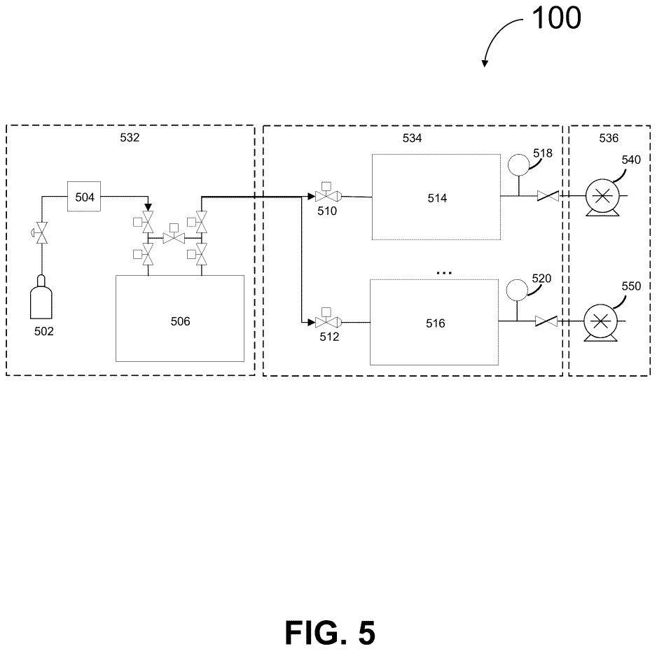

FIG. 5 is a schematic diagram of system 500 for precursor delivery, according to some embodiments. The system 500 for precursor delivery is same or similar to the system 100 for precursor delivery. Accordingly, similar reference numbers are used. Some of the differences between the system 500 for precursor delivery and the system 100 for precursor delivery are discussed. It will, however, be appreciated that other differences may exist, without departing from the scope of this disclosure.

As shown in FIG. 5, in some embodiments, the system 500 for precursor delivery comprises a carrier gas source 502, a precursor vessel 506, and a plurality of deposition chambers, such as, for example and without limitation, deposition chamber 514 and deposition chamber 516. A downstream pressure controller 504 can be provided at a location between the carrier gas source 502 and the precursor vessel 506. In some embodiments, the downstream pressure controller 504 comprises a control valve and a controller in a single unit. For example, the downstream pressure controller 504 can be configured to control a carrier gas flow from the carrier gas source 502 to the precursor vessel 506 based on an orifice restriction flow controller 510 at the inlet of deposition chamber 514 and an orifice restriction flow controller 512 at the inlet of deposition chamber 516. In addition, deposition chamber 514 can communicate with the orifice restriction flow controller 510, a pressure sensor 518, and a pump 540; and deposition chamber 516 can communicate with the orifice restriction flow controller 512, a pressure sensor 520, and a pump 550.

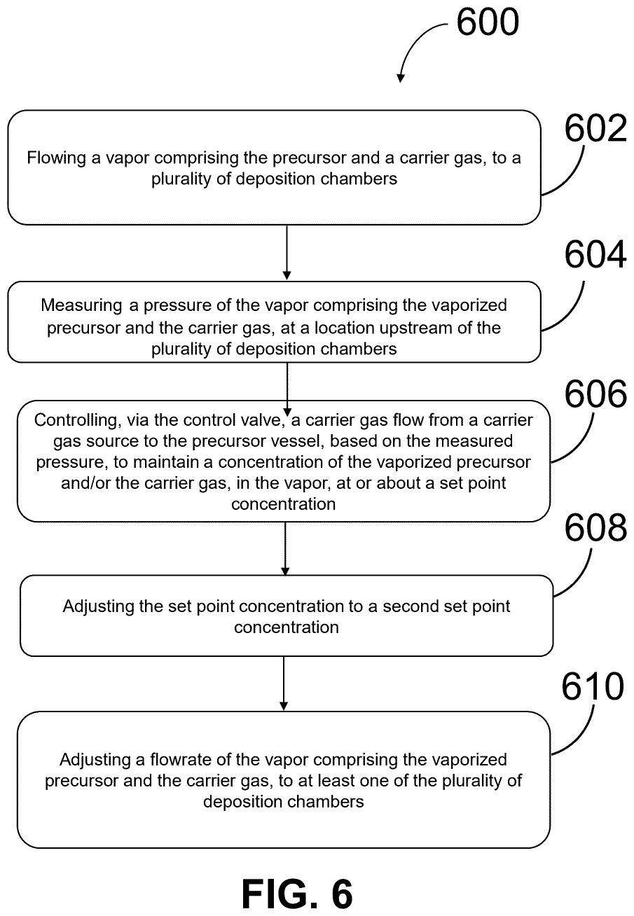

FIG. 6 is a flowchart of a method 600 for controlling a total pressure of the precursor vessel using a control valve, according to some embodiments. As shown in FIG. 6, the method 600 include one or more of the following steps: flowing a vapor comprising a vaporized precursor and a carrier gas, from a precursor vessel to a plurality of deposition chambers 602; measuring a pressure of the vapor comprising the vaporized precursor and the carrier gas, at a location upstream of the plurality of deposition chambers 604; controlling, via the control valve, a carrier gas flow from a carrier gas source to the precursor vessel, based on the measured pressure, to maintain a concentration of the vaporized precursor and/or the carrier gas, in the vapor, at or about a set point concentration 606; adjusting the set point concentration to a second set point concentration 608; and adjusting a flowrate of the vapor comprising the vaporized precursor and the carrier gas, to at least one of the plurality of deposition chambers 610.

At step 602, in some embodiments, the method 600 comprises flowing a vapor comprising a vaporized precursor and a carrier gas, from a precursor vessel to a plurality of deposition chambers. In some embodiments, the flowing comprises pumping the vapor from a precursor vessel to a plurality of deposition chambers. In some embodiments, the flowing comprises vacuuming the vapor from a precursor vessel to a plurality of deposition chambers. In some embodiments, the flowing comprises diffusing the vapor from a precursor vessel to a plurality of deposition chambers. In some embodiments, the flowing comprises flowing the vapor by means of convection from a precursor vessel to a plurality of deposition chambers. In some embodiments, the flowing comprises flowing the vapor by means of forced convection via a pump from a precursor vessel to a plurality of deposition chambers. In some embodiments, the flowing comprises flowing the vapor by means of natural convection via a fan from a precursor vessel to a plurality of deposition chambers.

At step 604, in some embodiments, the method 600 comprises measuring a pressure of the vapor comprising the vaporized precursor and the carrier gas, at a location upstream of the plurality of deposition chambers. The at least one pressure sensor can be used to measure a total pressure within the pressure vessel. The total pressure of the precursor vessel can be a proxy for the pressure of the vapor. In some embodiments, the measuring comprises sensing a total pressure of the precursor vessel using at least one pressure sensor. In some embodiments, the measuring comprises detecting a total pressure of the precursor vessel. In some embodiments, the measuring comprises detecting a total pressure of the precursor vessel. In some embodiments, the measuring comprises monitoring a total pressure of the precursor vessel as a proxy for the pressure of the vapor. In some embodiments, the measuring comprises identifying a total pressure of the precursor vessel.

At step 606, in some embodiments, the method 600 comprises controlling, via the control valve, a carrier gas flow from a carrier gas source to the precursor vessel, based on the measured pressure, to maintain a concentration of the vaporized precursor and/or the carrier gas, in the vapor, at or about a set point concentration. In some embodiments, the controlling comprises regulating via the control valve, a carrier gas flow from a carrier gas source to the precursor vessel, based on the measured pressure, to maintain a concentration of the vaporized precursor and/or the carrier gas, in the vapor, at or about a set point concentration. In some embodiments, the controlling comprises maintaining via the control valve, a carrier gas flow from a carrier gas source to the precursor vessel, based on the measured pressure, to maintain a concentration of the vaporized precursor and/or the carrier gas, in the vapor, at or about a set point concentration. In some embodiments, the controlling comprises adjusting via the control valve, a carrier gas flow from a carrier gas source to the precursor vessel, based on the measured pressure, to maintain a concentration of the vaporized precursor and/or the carrier gas, in the vapor, at or about a set point concentration. In some embodiments, the controlling comprises decreasing via the control valve, a carrier gas flow from a carrier gas source to the precursor vessel, based on the measured pressure, to maintain a concentration of the vaporized precursor and/or the carrier gas, in the vapor, at or about a set point concentration. In some embodiments, the controlling comprises increasing via the control valve, a carrier gas flow from a carrier gas source to the precursor vessel, based on the measured pressure, to maintain a concentration of the vaporized precursor and/or the carrier gas, in the vapor, at or about a set point concentration.

At step 608, in some embodiments, the method 600 comprises adjusting the set point concentration to a second set point concentration. In some embodiments, the adjusting is based on total pressure. In some embodiments, the adjusting is based on partial pressure.

At step 610, in some embodiments, the method 600 comprises adjusting a flowrate of the vapor comprising the vaporized precursor and the carrier gas, to at least one of the plurality of deposition chambers. In some embodiments, a flow controller is configured to adjust a flowrate to each of the plurality of deposition chambers. In some embodiments, a flow controller adjusts a flowrate to each of the plurality of deposition chambers using a flow control valve set by the set point concentration.

The flowrate to each of the plurality of deposition chambers can be different while maintaining a concentration of the vapor at a set point concentration. In some embodiments, each of the flow control valves is set to control the flowrate of the vapor to each of the plurality of deposition chambers at a different rate while maintaining a concentration of the vapor at a set point concentration. For example, in some embodiments, a flow rate of the vapor to a first deposition chamber is different from a flow rate of the vapor to a second deposition chamber.

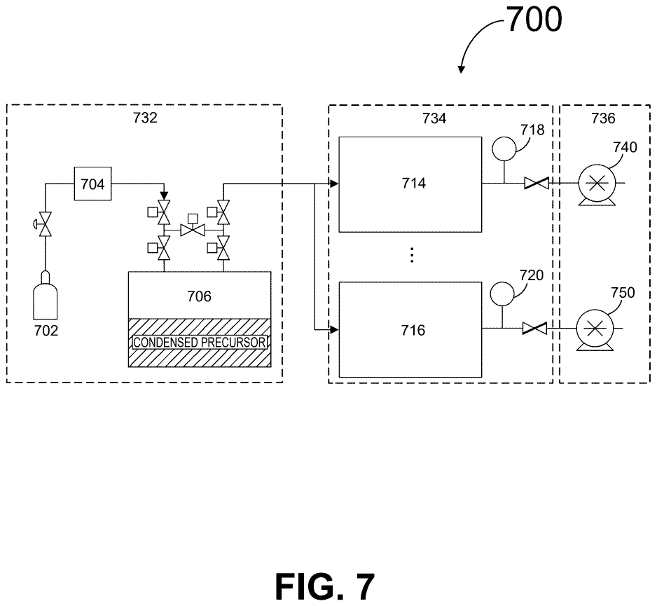

FIG. 7 is a schematic diagram of a prior art system 700 for precursor delivery which exhibits several challenges solved by the present invention. A standard delivery cabinet 732 that uses carrier gas 702 to deliver a target vapor is illustrated in the “sub-fab delivery to multiple tool configuration”. In this case an inert carrier gas flow 702 is controlled at a constant mass flow rate into an ampoule 706 that contains the liquid or solid precursor material as well as a headspace containing precursor vapor and carrier gas. If all of the deposition process chambers 714, 716 on the fab floor 734 are flowing at the same rate and all of the line conductances are the same, then the concentration of precursor arriving at each deposition tool is the same and constant. However, process tools turn on and off as a layer is starting or finishing for continuous CVD; for an ALD process, each tool turns flow on and off many time during each film deposition. (1000 cycles is not unusual to deposit a single film.) If the flow 704 into the precursor ampoule 706 is constant, but the flow out of the ampoule 706 is not constant, the total pressure builds up and drops in the ampoule 706 as process chambers 714, 716 cycle on and off. Since the saturated partial pressure of the precursor vapor is constant at a particular ampoule 706 temperature, the concentration of precursor vapor will change as the total pressure in the ampoule 706 changes.

One could imagine a control system where each deposition process chamber 714, 716 requested a certain flow from the sub-fab 732/remote delivery cabinet. In this case, an algorithm would need to be tuned to adjust flow to match what is requested by the tools. However, toolmakers generally only send a general “vapor request” signal before a period of time when they might want flow rather than a constant on and off signal. And they do not provide a signal that says the volume of flow requested. In addition, even if the flow in were adjusted on-the-fly as it was needed by the process chambers, the pressure drop through the outlet valves of the ampoule (718 and 719) will increase with increased flow. This leads to the total pressure in the headspace being different at different flows. Since the saturated partial pressure of the precursor vapor is constant at a particular ampoule 706 temperature, the concentration of precursor vapor will change as the total pressure in the ampoule changes.

In FIG. 7, the rightmost area is the vapor waste stream 736 which includes pumps 740 and 750.

### ASPECTS

Various Aspects are described below. It is to be understood that any one or more of the features recited in the following Aspect(s) can be combined with any one or more other Aspect(s).
Aspect 1. A system comprising:
   a control valve,
      wherein the control valve is configured to control a flow of a carrier gas from a carrier gas source to a precursor vessel containing a precursor;
   a pressure sensor,
      wherein the pressure sensor is configured to measure a pressure of a vapor comprising at least one of the carrier gas, the precursor, or any combination thereof; and
   a controller,
      wherein the controller communicates with the control valve and the pressure sensor;
      wherein the controller is configured to adjust the control valve based on the pressure measured by the at least one pressure sensor, such that, when the vapor is delivered to the plurality of deposition chambers at different flow rates, a concentration of the carrier gas and the precursor is substantially constant.
Aspect 2. The system according to Aspect 1, wherein the precursor vessel comprises only a single precursor vessel.
Aspect 3. The system according to any one of Aspects 1-2, wherein the plurality of deposition chambers comprises a first deposition chamber and a second deposition chamber.
Aspect 4. The system according to any one of Aspects 1-3, wherein each of the plurality of deposition chambers comprises a flow control for independently controlling a flow rate of the vapor to each of the plurality of deposition chambers.
Aspect 5. The system according to any one of Aspects 1-4, wherein the control valve is part of a downstream pressure controller (DPC).
Aspect 6. The system according to any one of Aspects 1-5, wherein the control valve is not a part of a mass flow controller (MFC).
Aspect 7. The system according to any one of Aspects 1-6, wherein the control valve comprises at least one of a variable orifice valve, an electrovalve, or any combination thereof.
Aspect 8. The system according to any one of Aspects 1-7, wherein the pressure sensor is located between the control valve and the plurality of deposition chambers.
Aspect 9. The system according to any one of Aspects 1-8, wherein the pressure sensor is located between the carrier gas source and the precursor vessel.
Aspect 10. The system according to any one of Aspects 1-9, wherein the pressure sensor is located at the precursor vessel and is configured to measure a total pressure in the precursor vessel.
Aspect 11. The system according to any one of Aspects 1-10, wherein the pressure sensor is located between the control valve and the precursor vessel.
Aspect 12. The system according to any one of Aspects 1-11, wherein the pressure sensor is located between the precursor vessel and the plurality of deposition chambers.
Aspect 13. The system according to any one of Aspects 1-12, wherein the pressure sensor comprises:
   a first pressure sensor located between the control valve and the precursor vessel; and
   a second pressure sensor located between the precursor vessel and the plurality of deposition chambers.
Aspect 14. The system according to any one of Aspects 1-13, wherein the control valve is not located on a fabrication area of a semiconductor manufacturing facility.
Aspect 15. A system comprising:
   a precursor vessel fluidly coupled to a carrier gas source,
      wherein the precursor vessel is configured to:
         contain a precursor, and
         deliver a vapor comprising the precursor and a carrier gas, to a plurality of deposition chambers;
   a control valve,
      wherein the control valve is configured to maintain a sensed total pressure of the vapor in the precursor vessel; and
      wherein the control valve is located in a flow path of the carrier gas at a location upstream of the precursor vessel; and
   at least one pressure sensor,
      wherein the at least one pressure sensor is located in a flow path of the vapor between the control valve and the plurality of deposition chambers.
Aspect 16. The system according to Aspect 15,
   wherein the plurality of deposition chambers is located in the flow path of the vapor at a location downstream of the precursor vessel; and
   wherein each of the plurality of deposition chambers is configured to receive the vapor at an independently adjustable flow rate.
Aspect 17. The system according to any one of Aspects 15-16, wherein the control valve adjusts a total pressure of the precursor vessel within 10% of a set point pressure based on the sensed total pressure.
Aspect 18. The system according to any one of Aspects 15-17, wherein the control valve is in communication with the at least one pressure sensor located at an inlet of the precursor vessel and at least one pressure sensor at an outlet of the precursor vessel.
Aspect 19. The system according to any one of Aspects 15-18, wherein the at least one pressure sensor is located at least one of an outlet of the control valve, an inlet of the precursor vessel, an outlet of the precursor vessel, or any combination thereof.
Aspect 20. The system according to any one of Aspects 15-19, further comprising:
   a plurality of flow control valves,
      wherein the plurality of flow control valves is located in a flow path of the vapor at a location upstream of each of the plurality of deposition chambers,
      wherein the plurality of flow control valves is configured to adjust a flow rate to each of the plurality of deposition chambers.
Aspect 21. The system according to any one of Aspects 15-20, wherein the plurality of flow control valves comprises at least one of a mass flow controller, a restricted flow orifice element, or any combination thereof.
Aspect 22. The system according to any one of Aspects 15-21, wherein a total pressure of the precursor vessel is greater than a deposition pressure.
Aspect 23. The system according to any one of Aspects 15-22,
   wherein the carrier gas source is located in a sub-fabrication area;
   wherein the precursor vessel is located in the sub-fabrication area; and
   wherein the control valve is located in the sub-fabrication area.
Aspect 24. The system according to any one of Aspects 15-23,
   wherein the carrier gas source is located in a sub-fabrication area;
   wherein the precursor vessel is located in the sub-fabrication area; and
   wherein the control valve is located in a fabrication area.
Aspect 25. The system according to any one of Aspects 15-24,
   wherein the plurality of flow control valves is located in a fabrication area; and
   wherein the plurality of deposition chambers is located in a fabrication area.
Aspect 26. A method comprising:
   flowing a vapor comprising a vaporized precursor and a carrier gas, from a precursor vessel to a plurality of deposition chambers;
   measuring a pressure of the vapor comprising the vaporized precursor and the carrier gas, at a location upstream of the plurality of deposition chambers,
   controlling, via the control valve, a carrier gas flow from a carrier gas source to the precursor vessel, based on the measured pressure, to maintain a concentration of the vaporized precursor and/or the carrier gas, in the vapor, at or about a set point concentration;
   adjusting the set point concentration to a second set point concentration; and
   adjusting a flowrate of the vapor comprising the vaporized precursor and the carrier gas, to at least one of the plurality of deposition chambers.
Aspect 27. The method according to Aspect 26, wherein adjusting the flowrate comprises controlling, via a plurality of flow control valves.
Aspect 28. The method according to any one of Aspects 26-27, wherein each of the plurality of deposition chambers receives the vapor at an independently adjustable flow rate.
Aspect 29. The method according to any one of Aspects 26-28, further comprising:
   vaporizing the vapor in the precursor vessel to obtain the vapor at a target temperature.
Aspect 30. The method according to any one of Aspects 26-29, wherein control valve adjusts a total pressure of the precursor vessel within 10% of a set point pressure based on a sensed total pressure.
Aspect 31. The method according to any one of Aspects 26-30, wherein the plurality of flow control valves comprises at least one of a mass flow controller, a restricted flow orifice element, or any combination thereof.
Aspect 32. The method according to any one of Aspects 26-31, wherein the total pressure of the precursor vessel is greater than a deposition pressure.
Aspect 33. The method according to any one of Aspects 26-32, wherein the control valve is in communication with the at least one pressure sensor located at an inlet and an outlet of the precursor vessel.
Aspect 34. The method according to any one of Aspects 26-33, wherein the at least one pressure sensor is located at the control valve.

What is claimed is:

1. A system comprising:
a control valve,
wherein the control valve is configured to control a flow of a carrier gas from a carrier gas source to a precursor vessel containing a precursor;
a pressure sensor,
wherein the pressure sensor is configured to measure a pressure of a vapor comprising at least one of the carrier gas, the precursor, or any combination thereof; and
a controller,
wherein the controller communicates with the control valve and the pressure sensor;
wherein the controller is configured to adjust the control valve based on the pressure measured by the at least one pressure sensor, such that, when the vapor is delivered to the plurality of deposition chambers at different flow rates, a concentration of the carrier gas and the precursor is substantially constant.

2. The system of claim 1, wherein the precursor vessel comprises only a single precursor vessel.

3. The system of claim 1, wherein the plurality of deposition chambers comprises a first deposition chamber and a second deposition chamber.

4. The system of claim 1, wherein each of the plurality of deposition chambers comprises a flow control for independently controlling a flow rate of the vapor to each of the plurality of deposition chambers.

5. The system of claim 1, wherein the control valve is part of a downstream pressure controller (DPC).

6. The system of claim 1, wherein the control valve is not a part of a mass flow controller (MFC).

7. The system of claim 1, wherein the control valve comprises at least one of a variable orifice valve, an electrovalve, or any combination thereof.

8. The system of claim 1, wherein the pressure sensor is located between the control valve and the plurality of deposition chambers.

9. The system of claim 1, wherein the pressure sensor is located between the carrier gas source and the precursor vessel.

10. The system of claim 1, wherein the pressure sensor is located at the precursor vessel and is configured to measure a total pressure in the precursor vessel.

11. The system of claim 1, wherein the pressure sensor is located between the control valve and the precursor vessel.

12. The system of claim 1, wherein the pressure sensor is located between the precursor vessel and the plurality of deposition chambers.

13. The system of claim 1, wherein the pressure sensor comprises:
a first pressure sensor located between the control valve and the precursor vessel; and
a second pressure sensor located between the precursor vessel and the plurality of deposition chambers.

14. The system of claim 1, wherein the control valve is not located on a fabrication area of a semiconductor manufacturing facility.

15. A system comprising:
a precursor vessel fluidly couplable to a carrier gas source
wherein the precursor vessel is configured to:
contain a precursor, and
deliver a vapor comprising the precursor and a carrier gas, to a plurality of deposition chambers;
a control valve,
wherein the control valve is configured to maintain a sensed total pressure of the vapor in the precursor vessel; and
wherein the control valve is located in a flow path of the carrier gas at a location upstream of the precursor vessel; and
at least one pressure sensor,
wherein the at least one pressure sensor is located in a flow path of the vapor between the control valve and the plurality of deposition chambers.

16. The system of claim 15,
wherein the carrier gas source is located in a sub-fabrication area;
wherein the precursor vessel is located in the sub-fabrication area; and
wherein the control valve is located in the sub-fabrication area.

17. The system of claim 15,
wherein the carrier gas source is located in a sub-fabrication area;
wherein the precursor vessel is located in the sub-fabrication area; and
wherein the control valve is located in a fabrication area.

18. A method comprising:
flowing a vapor comprising a vaporized precursor and a carrier gas, from a precursor vessel to a plurality of deposition chambers;
measuring a pressure of the vapor comprising the vaporized precursor and the carrier gas, at a location upstream of the plurality of deposition chambers,
controlling, via the control valve, a carrier gas flow from a carrier gas source to the precursor vessel, based on the measured pressure, to maintain a concentration of the vaporized precursor and/or the carrier gas, in the vapor, at or about a set point concentration;
adjusting the set point concentration to a second set point concentration; and
adjusting a flowrate of the vapor comprising the vaporized precursor and the carrier gas, to at least one of the plurality of deposition chambers.

19. The method of claim 18, further comprising:
vaporizing the vapor in the precursor vessel to obtain the vapor at a target temperature.

20. The method of claim 18, wherein the control valve is in communication with the at least one pressure sensor located at an inlet and an outlet of the precursor vessel.
